(19) United States
(12) Patent Application Publication
(10) Pub. No.: US 2026/0017436 A1
(43) Pub. Date: Jan. 15, 2026

(54) SYSTEM AND METHOD FOR DESIGN-TECHNOLOGY CO-OPTIMIZATION PHYSICAL DESIGN PERFORMANCE OPTIMIZATION

(71) Applicant: Samsung Electronics Co., Ltd., Gyeonggi-do (KR)

(72) Inventors: Duo DING, Austin, TX (US); Kevin Immanuel GUBBI, San Diego, CA (US); Brad KIDDIE, Austin, TX (US); Matthew STREYLE, Austin, TX (US)

(21) Appl. No.: 19/265,064

(22) Filed: Jul. 10, 2025

Related U.S. Application Data
(60) Provisional application No. 63/669,666, filed on Jul. 10, 2024.
(60) Provisional application No. 63/783,668, filed on Apr. 4, 2025.

(51) Int. Cl. G06F 30/27; G06F 16/901; G06F 30/12; G06F 30/337

(52) U.S. Cl. CPC G06F 30/27; G06F 16/9024; G06F 30/12; G06F 30/337

(57) ABSTRACT

A system and a method are provided for improving power, performance and area (PPA) optimization using data intelligence and visualization in design-technology co-optimization (DTCO) processes. A method includes generating a database including a plurality of entries corresponding to semiconductor chip design life cycles; generating a graphical representation of at least one of the plurality of entries; operating a framework including a plurality of techniques for identifying factors contributing to an optimal chip design, based on the graphical representation; and outputting a completed chip design based on the identified factors.

### CROSS-REFERENCE TO RELATED APPLICATION

This application claims the priority benefit under 35 U.S.C. § 119(e) of U.S. Provisional Application Nos. 63/669,666 and 63/783,668, which were filed on Jul. 10, 2024, and Apr. 4, 2025, respectively, the disclosure of each of which is incorporated by reference in its entirety as if fully set forth herein.

### TECHNICAL FIELD

The disclosure generally relates to semiconductor device design. More particularly, the subject matter disclosed herein relates to improvements for power, performance and area (PPA), cost, and turn-around-time optimization using data intelligence and visualization in design-technology co-optimization (DTCO) processes.

### SUMMARY

Electronic design automation (EDA) methods or devices may be used to find an input (or test) pattern (or sequence) that, when applied to a digital circuit, enables automatic test equipment (ATE) to distinguish between correct circuit behavior and faulty circuit behavior caused by defects in the digital circuit. For example, generated patterns may be used to test semiconductor devices, or to assist with determining a cause of failure.

Effectiveness of an EDA method measured by a number of modeled defects, or fault models, detectable and by the number of generated patterns. These metrics generally indicate test quality (higher with more fault detections) and test application time (higher with more patterns).

A defect is an error caused in a device during the manufacturing process. A fault model is a mathematical description of how a defect alters design behavior. The logic values observed at the device's primary outputs, while applying a test pattern to some device under test, are called the output of that test pattern. The output of a test pattern, when testing a fault-free device that works exactly as designed, is called the expected output of that test pattern. A fault is said to be detected by a test pattern if the output of that test pattern, when testing a device that has only that one fault, is different than the expected output.

However, EDA methods often fail to find a test for a particular fault, e.g., it is possible that a detection pattern exists, but the algorithm cannot find one.

Additionally, the current methodology for selecting a transitional delay fault (TDF) pattern as an input to an EDA for intermediate resistance (IR) drop analysis mainly relies on a switching activity report generated by an EDA tool. More specifically, a switching activity report provides a total number of toggling flops during capture cycle per pattern. IR drop analysis is then conducted using a pattern with a highest number of toggling flops in the switching activity report. However, relying on the above-described switching activity report methodology still results in high frequency transitional patterns failing that can only be addressed by many iterations of diagnostics often over weeks and many flop maskings, which could potentially impact test coverage for a given pattern. As a result, critical issues are often not detected in pre tape-out (TO) analysis and are often only observed fabrication on to a silicon wafer.

The TO process is also a significant financial commitment. Once a design is taped out, masks required for production are created. These masks, which are used to transfer the design onto the silicon wafer during the fabrication process, are expensive to produce. As such, any errors discovered after TO can lead to the creation of a new set of masks, significantly increasing the costs.

To overcome these issues, systems and methods are described herein, which may be used to improve PPA, cost, and turn-around-time competitiveness in the design of components, such as a central processing unit (CPU), a graphics processing unit (GPU), a neural processing unit (NPU), a system-on-chip (SOC), etc., by utilizing data intelligence and visualization in DTCO processes.

The embodiments described herein improve on previous methods by:
collecting and leveraging data generated in semiconductor chip design, and co-optimizing foundry technologies and design features for improved PPA scores;
storing and representing key data in chip building steps with unique data structures and exploring insights with artificial intelligence (AI)/machine learning (ML) algorithms/flows; deriving metrics and insights to score chip PPA, cost, and turn-around-time competitiveness;
implementing targeted algorithms and AI methods to improve chip design and/or perform treat-offs to mitigate silicon risks;
efficiently exploring solution spaces that have not been exploited due to compute resource and runtime limitations;
fully leveraging chip design data through automated AI and ML flows; and
providing algorithms/methods/visualizations to handle challenging chip design features inside mobile GPUs, such as advanced gaming, low power modes, and automobile applications, etc.

In an embodiment, a method is provided that includes generating a database including a plurality of entries corresponding to semiconductor chip design life cycles; generating a graphical representation of at least one of the plurality of entries; operating a framework including a plurality of techniques for identifying factors contributing to an optimal chip design, based on the graphical representation; and outputting a completed chip design based on the identified factors.

In an embodiment, a computing device is provided that includes at least one processor; and memory configured to store instructions, which when executed by the at least one processor, control the processor to generate a database including a plurality of entries corresponding to semiconductor chip design life cycles, generate a graphical representation of at least one of the plurality of entries, operate a framework including a plurality of techniques for identifying factors contributing to an optimal chip design, based on the graphical representation, and output a completed chip design based on the identified factors.

In an embodiment, a non-transitory computer readable medium is provided for storing program codes, which when executed by a computing device, control the computing device to generate a database including a plurality of entries corresponding to semiconductor chip design life cycles, generate a graphical representation of at least one of the plurality of entries, operate a framework including a plurality of techniques for identifying factors contributing to an optimal chip design, based on the graphical representation, and output a completed chip design based on the identified factors.

### BRIEF DESCRIPTION OF THE DRAWING

In the following section, the aspects of the subject matter disclosed herein will be described with reference to exemplary embodiments illustrated in the figures, in which:

FIG. 1 illustrates an example computing device according to an embodiment;

FIG. 2 illustrates an example semiconductor system, according to an embodiment;

FIG. 3 illustrates a method of semiconductor chip design process, according to an embodiment;

FIG. 4 is a flow chart illustrating a method, according to an embodiment;

FIG. 5 is a flow chart illustrating a method of creating a database, according to an embodiment;

FIG. 6 is a flow chart illustrating a method of performing graph analysis, according to an embodiment;

FIG. 7 is a flow chart illustrating a method utilizing reinforcement learning (RL) to identify optimal design configurations, according to an embodiment;

FIG. 8 is a block diagram of an electronic device in a network environment 800, according to an embodiment; and

FIG. 9 shows a system including a UE and a gNB, in communication with each other.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

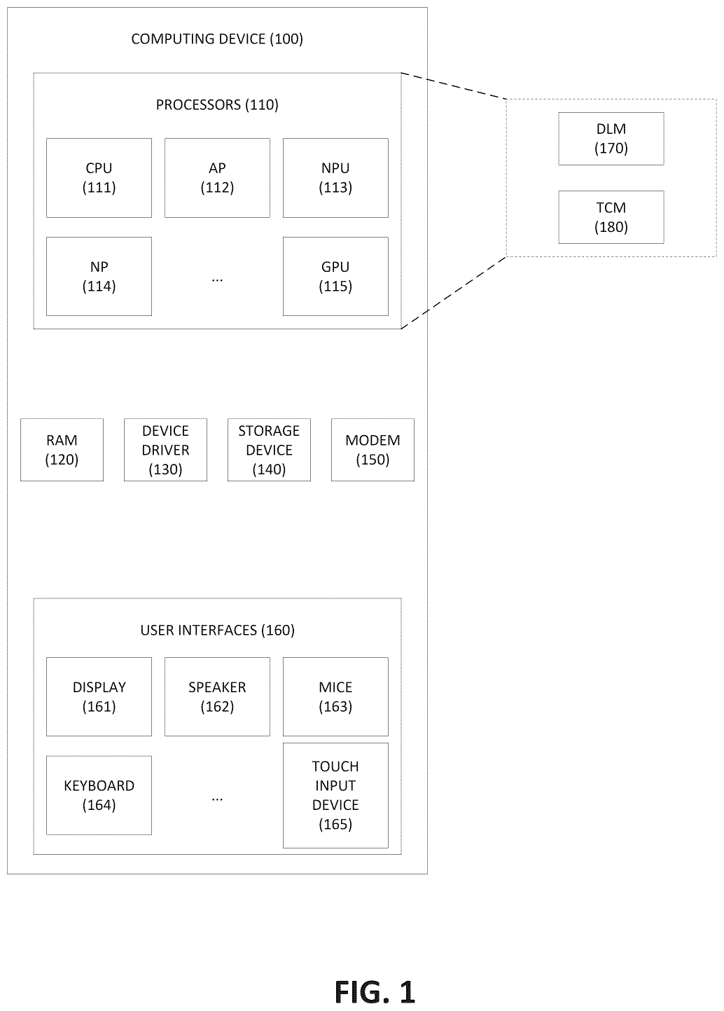

FIG. 1 illustrates an example computing device, according to an embodiment.

Referring to FIG. 1, a computing device 100 may include processors 110, a random access memory (RAM) 120, a device driver 130, a storage device 140, a modem 150, and a user interface (UI) 160.

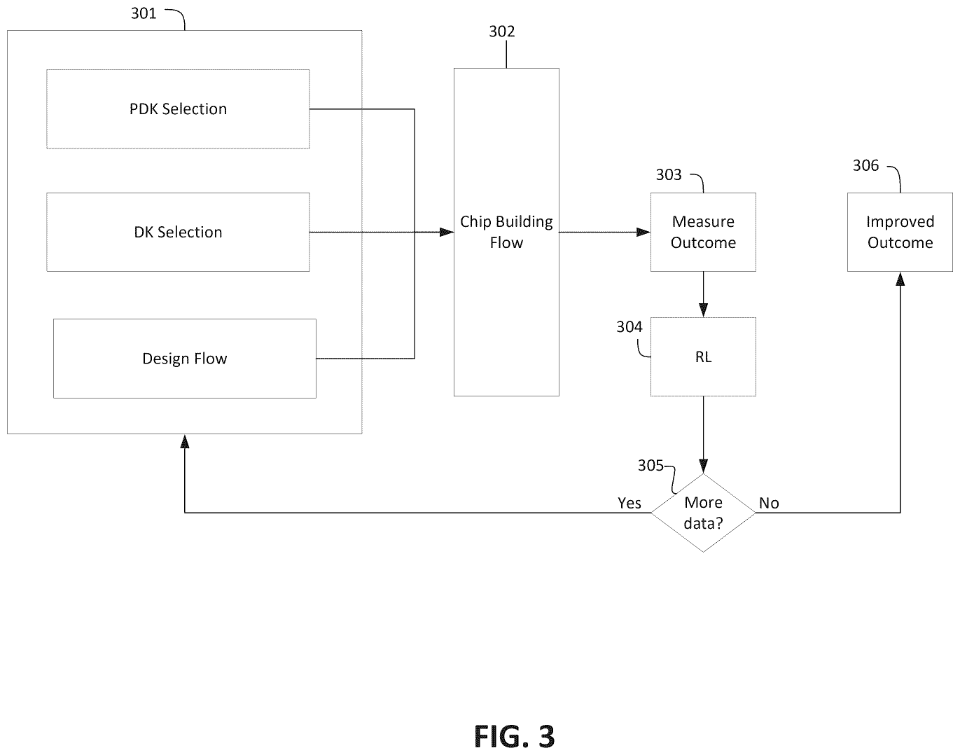

At least one processor of the processors 110 may be configured to operate a deep learning model (DLM) 170 and a training control module (TCM) 180. The TLM 180 may perform the methods of FIGS. 3 to 7 to train the DLM 170.

In some example embodiments, the DLM 170 and the TCM 180 may be implemented as instructions (and/or program codes) that may be executed by the at least one of the processors 110. The instructions (and/or program codes) of the DLM 170 and the TCM 180 may be stored in computer readable media. For example, the at least one processor may load (and/or read) the instructions to (and/or from) the RAM 120.

In some example embodiments, the at least one processor may be manufactured to efficiently execute instructions included in the DLM 170 and the TCM 180. For example, the at least one processor may be a dedicated processor that is implemented (e.g., in hardware) based on the DLM 170 and the TCM 180. The at least one processor may efficiently execute instructions from various machine learning modules. In some embodiments, at least one processor may receive information corresponding to the DLM 170 and the TCM 180 to operate the DLM 170 and the TCM 180.

The processors 110 may include, for example, at least one general-purpose processor such as a central processing unit (CPU) 111, an application processor (AP) 112, and/or other processing units. In addition, the processors 110 may include at least one special-purpose processor such as a neural processing unit (NPU) 113, a neuromorphic processor (NP) 114, a graphic processing unit (GPU) 115, etc. For example, the processors 110 may include two or more heterogeneous processors. Though illustrated as including the CPU 111, AP 112, NPU 113, NP 114, and GPU 115, the example embodiments are not so limited. For example, the processors 110 may include more or fewer processors than illustrated.

The RAM 120 may be used as an operation memory of the processors 110, a main memory, and/or a system memory of the computing device 100. The RAM 120 may include a volatile memory such as a dynamic RAM (DRAM), a static RAM (SRAM), and/or the like. Additionally (and/or alternatively), the RAM 120 may include a nonvolatile memory such as a phase-change RAM (PRAM), a ferroelectrics RAM (FRAM), a magnetic RAM (MRAM), a resistive RAM (RRAM), and/or the like.

The device driver 130 may control peripheral circuits such as the storage device 140, the modem 150, the UI 160, etc., according to requests of the processors 110. The storage device 140 may include a fixed storage device such as a hard disk drive, a solid state drive (SSD), etc., and/or include (and/or be connected to) an attachable storage device such as an external hard disk drive, an external SSD, a memory card, and/or other external storage.

The modem 150 may perform wired or wireless communication with external devices through various communication methods and/or communication interface protocols such as Ethernet, WiFi, LTE, a third generation communication system such as code division multiple access (CDMA), global system for mobile communications (GSM), north American digital cellular (NADC), extended-time division multiple access (E-TDMA), and/or wide band code division multiple access (WCDMA), a fourth generation communication system such as 4G LTE, a fifth generation communication system such as 5G mobile communication, and/or other communication methods.

The UI 160 may receive information from a user and provide information to the user. The UI 160 may include at least one output interface such as a display 161, a speaker 162, etc., and may further include at least one input interface such as mice (mouse) 163, a keyboard 164, a touch input device 165, etc. Though illustrated as including the display 161, the speaker 162, the mouse, 163, the keyboard 164, and the touch input device 165, the example embodiments are not so limited, and may, e.g., include more or fewer elements. In some example embodiments, some of the UIs 160 may be combined (e.g., to include a touch screen).

In some example embodiments, the DLM 170 and the TCM 180 may receive the instructions (and/or codes) through the modem 150 and store the instructions in the storage device 150. In some example embodiments, the instructions of the DLM 170 and the TCM 180 may be stored in an attachable storage device and the attachable storage device may be connected to the computing device 100 by a user. The instructions of the DLM 170 and the TCM 180 may be loaded in the RAM 120 for rapid execution of the instructions.

In some example embodiments, at least one of computer program codes, a compact model, a DLM and/or a TCM may be stored in a transitory and/or non-transitory computer-readable medium. In some example embodiments, values resulting from a simulation performed by the processor and/or values obtained from arithmetic processing performed by the processor may be stored in a transitory and/or non-transitory computer-readable medium. In some example embodiments, intermediate values generated during deep learning may be stored in a transitory and/or non-transitory computer-readable medium. In some example embodiments, at least one of the training data, the process data, the device data, the simulation result data, the prediction data, and/or the uncertainty data may be stored in a transitory or non-transitory computer-readable medium. However, the example embodiments are not limited thereto.

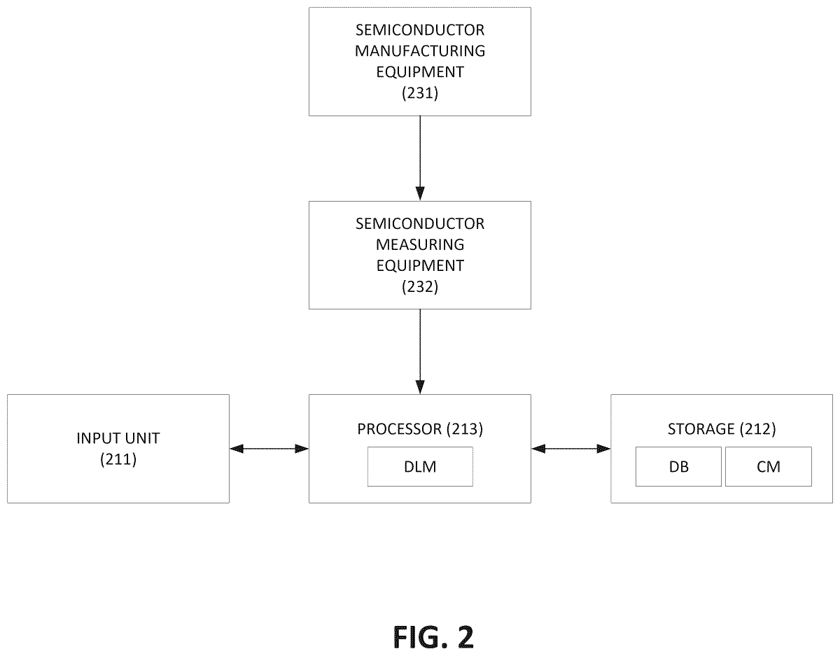

FIG. 2 illustrates an example semiconductor system, according to an embodiment.

Referring to FIG. 2, the semiconductor system includes an input unit 211, a storage 212, a processor 213, semiconductor manufacturing equipment 231, and semiconductor measuring equipment 232. In some example embodiments, a semiconductor system may include the input unit 211, the storage 212, and the processor 213, separated from the semiconductor manufacturing equipment 231 and the semiconductor measuring equipment 232.

The storage 212 may include a compact model (CM) and a database (DB).

The input unit 211 may receive device data and transmit the device data to the processor 213, and the processor 213 may generate basic training data using the CM. The CM may provide simulation result data indicating characteristics of a semiconductor device corresponding to the device data by performing simulation based on the device data. For example, in some example embodiments, the input unit 211 may be (and/or include) at least one of the user inputs, storage device 140, and/or modem 150, and the processor 213 may be (and/or include) at least one of the processors 100 (as illustrated in FIG. 1).

The processor 213 may generate training data corresponding to a combination of the device data and the simulation result data. The processor 213 may obtain values of the simulation result data corresponding to various values of the device data and establish the DB including various combinations of the values of the device data and the simulation result data. The processor 213 may perform training or learning of a DLM using the training data in the DB.

The processor 213 may generate (and/or update) the CM based on measurement data and store/update the CM in the storage 212.

The CM may be generated (and/or updated) based on the measurement data. The measurement data may include an electrical and/or structural characteristic of a semiconductor product actually measured by the semiconductor measuring equipment 232. The semiconductor product measured by the semiconductor measuring equipment 232 may have been manufactured by the semiconductor manufacturing equipment 231 based on semiconductor manufacturing data. The semiconductor manufacturing data may be related to a manufacture of a target semiconductor device and/or a manufacture of a semiconductor device similar to the target semiconductor device.

The CM may be updated in response to the measurement of an electrical and/or structural characteristic of a semiconductor product by the semiconductor measuring equipment 232. For example, in response to the reception of the measurement data from the semiconductor measuring equipment 232, the processor 213 may update the CM to reflect the latest measurement data. The processor 213 may receive the measurement data from the semiconductor measuring equipment 232 through the input unit 211 or a communication unit.

The storage 212 may include equipment information of at least one selected from the semiconductor manufacturing equipment 231 and/or the semiconductor measuring equipment 232. For example, a semiconductor product may have a different electrical and/or structural characteristic according to the type of the semiconductor manufacturing equipment 231. In addition, the electrical and/or structural characteristic of a semiconductor product may be differently measured according to the type of the semiconductor measuring equipment 232. To reduce the potential for errors involved in the types of the semiconductor manufacturing equipment 231 and the semiconductor measuring equipment 232, the storage 212 may include various kinds of equipment information such as information about a manufacturer of the semiconductor manufacturing equipment 231 and/or a manufacturer of the semiconductor measuring equipment 232, model information of the semiconductor manufacturing equipment 231 and the semiconductor measuring equipment 232, and/or performance information thereof, e.g., PPA. The processor 213 may update the CM with reference to the equipment information stored in the storage 212.

The processor 213 may use the DLM, the CM, and/or the DB to simulate and/or predict the performance of a semiconductor device manufactured by the semiconductor manufacturing equipment 231, e.g., before the semiconductor device is manufactured. The processor 213 may, for example, determine whether a change to the design of the semiconductor device may improve or deteriorate the performance of the semiconductor device based on, e.g., operational conditions for the semiconductor device. In some example embodiments, for example, the processor 213 may confirm a design based on these predictions thereby indicating that the design is okay to proceed to manufacturing and/or forwarding the design to a processor controlling the semiconductor manufacturing equipment 231. The semiconductor manufacturing equipment 231 may then manufacture a semiconductor device based on the confirmed design. The processor 213 may also pause (and/or stop) the production of semiconductor devices based on the design if, e.g., the change in the design would result in a characteristic of the semiconductor devices deteriorating below a threshold value. In some example embodiments a warning and/or a representation of how and/or what characteristics are affected by the change in the design may be provided to a user (e.g., on the display 161 and/or through the modem 150 of FIG. 1).

In some example embodiments, the processor 213 may also (e.g., periodically) confirm the prediction of the DLM by comparing the prediction of a design with a semiconductor device manufactured based on the design, e.g., by using the measurement data received from the semiconductor measuring equipment 232 and/or using a data uncertainty value. For example, in some example embodiments, the processor 213 may store the prediction in the storage 212, and then may compare the prediction to the semiconductor device manufactured based on the design. If the prediction and the manufactured semiconductor device differ, e.g., beyond a maximum threshold, the CM stored in the storage 12 may be updated based on the measurement data actually measured by the semiconductor measuring equipment 232.

FIG. 3 illustrates a method of semiconductor chip design process, according to an embodiment.

Referring to FIG. 3, at 301, the basic design components of a semiconductor chip, i.e., process design kit (PDK), design kit, and design flow, are selected. Each of these basic design components include varying factors/choices that may affect PPA. A PDK may include a collection of data, models, and design rules that enable chip designers to create integrated circuits (ICs) that can be manufactured using a specific fabrication process. A DK, which may encompass a PDK, can also include other elements such as cell libraries, memory instances, IP blocks, etc. For example, PDK and/or DK selection may include the selection of optimal transistors (e.g., type, drive, sizing, threshold voltage, etc.), selection of an optimal library of cells (e.g., type, drive, sizing, threshold voltage, mixed-vt, hyper cells, etc.), selection of optimal metal stacks, or selection of optimal process, voltage, temperature (PVT) conditions.

A design flow refers to a sequence of steps and tools used to transform a chip's architectural and system requirements into a physical layout ready for manufacturing. For example, the design flow selection may include selection of vendor products, and version numbers, selection of optimization targets, i.e., 30% leakage+70% dynamic power, versus 100% timing, versus 50% area+50% total power, selection of EDA application options, e.g., chip placement strategies, clock tree synthesis algorithms used, versus place-and-route iteration numbers, and/or selection of other environment variables that configure design flow differently for improved design closure.

At 302, chip building flow is performed. More specifically, chip building flow is performed with regard to the vectorized configurations of the selected PDK, PK, and design flow factors.

At 303, an outcome of the chip building flow is measured. For example, the measurements of chip design outcome, i.e., performance, power, area, cost (peak and average compute resources in CPU, memory, disks, etc.), turn-around-time, are performed by collecting key metrics from the design database with automation scripts. These metrics may fall in general categories, such as cell-based metrics (e.g., percentage of cell types, in each block, sub-block, length of logic chains in critical timing path, critical timing cones and timing reports, setup and hold timing buffers hotspots, etc.), density-based metrics (e.g., layer utilization rate, net routing rate, track utilization rate, gate density, etc.), power (e.g., dynamic, leakage power, internal power, etc.), area (e.g., cell, block, or sub-block areas), quality of results (QoR) (e.g., design rule violations, power rail reliability hotspots, number of opens/shorts, etc.). Additionally, finer-grid metrics may be utilized that dive into each item to provide more details.

At 304, RL operations are performed on the measure outcome. More specifically, multi-database, agentic RL system may be utilized. At 305, a determination is made as to whether more data is required, and if yes, output of the RL operations are returned to 302, and the process is repeated.

More specifically, this type of RL may continue iteratively until it is determined at 305 that the process is completed (e.g., successfully meets pre-set targets of training/validation) or new data should be created in order to boost the accuracies of the RL system.

Within 304, existing data in the database is recycled and best-case active learning may be performed in the existing solution space.

Each time the flow goes through 305, new data are created and added to the database.

If no more data is required at 305, e.g., after a number of iterations, an improved outcome is provided at 306. For a best turn around time (TAT) of the flow, number of iterations should be minimized; however, the QoR generally improves with a larger dataset. Accordingly, there should be a balancing between TAT and QoR.

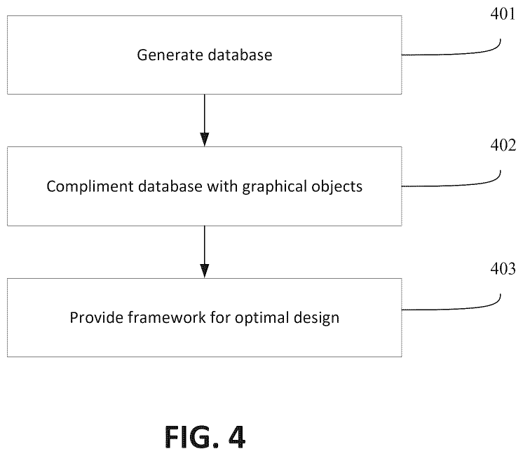

FIG. 4 is a flow chart illustrating a method, according to an embodiment.

Referring to FIG. 4, in step 401, a database is a generated. More specifically, a database may be constructed to store and search for information at each step of a semiconductor chip design life cycle, from PDK/DK content selection to various ways to configure the actual design flows. The database may store and index key performance indicators (KPIs) and metrics at each step of the chip design life cycle, with meta data tags. The database entries are tagged with meta data to facilitate KPIs and metrics that identify the status of a chip in PPA, cost, and/or turn-around-time, to facilitate searching entries that are associated with other entries, e.g., w.r.t a KPI, to facilitate high coverage of an entire chip PPA space per each dimension of factors, e.g., at 301 in FIG. 3.

This type of data may be used to identify weak coverage space and recommend extrapolation/augmentation and/or new rounds of design life cycles.

In step 402, the database is complimented with graphical objects. More specifically, the database may be complimented by representing connectivity centric data with graphical objects (e.g., graphs, histograms, heatmaps, dynamic tables) with proper interdependencies. That is, the database may be complimented with graphical objects to represent KPIs and metrics in a chip design that are best represented by connectivity. For example, given a common set of library cells, if a design requires a high degree of connectivity between the cell nodes, then the best selection of technology and design factors could vary drastically compared to a set with lower degree of connectivity.

The graphical objects may represent correlations between graphs structures, and allow for the use of powerful software engineering utilities such as graph neural networks. That is, tables, heatmaps, auto-correlations, graph analysis, histograms, and/or active learning algorithms may be used to speed up insight discovery, and graph neural networks may be used for a predictive analysis pipeline. This allows KPIs to be predicted with graph neural networks and also may be used to identify weak coverage space and recommend extrapolation/augmentation and/or new rounds of design life cycles.

In step 403, a framework is provided for optimal design. More specifically, a comprehensive framework with various techniques may be utilized to identify the selection of factors that contribute to an optimal chip design, such that a complete chip design may be output, e.g., via the user interfaces 160 of FIG. 1, based on the identified factors. The various techniques may include RL, applying replay buffers to allow deep focus AI learning using attention mechanisms, applying agentic flows to allow actor-critic and adversarial style enhancement in training AI models, providing methods to identify weak coverage of an entire solution space and recommend new simulation configurations to increase coverage confidence of prediction, providing methods to identify heavily samples and high confidence sub solution space in the database and focus on building AI models in the sub-solution space to yield high prediction confidence, providing methods for handling high dimensionalities of factors that are variables to AI methods, e.g., ranging from a dimension of 500 to 50000, providing methods to rank importance of varying input factors, and search for optimal combinations of input factors yielding optimal chip design outcomes, and/or providing methods to avoid penalties of local greedy methods, and/or to allow a short-term penalty (during early stages of chip design, such as early planning or cell placement) if that contributes to a long-term improvement in the chip design life cycle (such as routing or chip finishing engineering change order (ECO) steps).

Accordingly, the framework may be used to navigate large design space for optimal design, e.g., best PPA vs. input knobs (e.g., voltage threshold (VT), drive strength (D), channel length (L), cell height (CH), and/or cell distribution (vectorized percentage of usage among VT, D, L, NS and CH)).

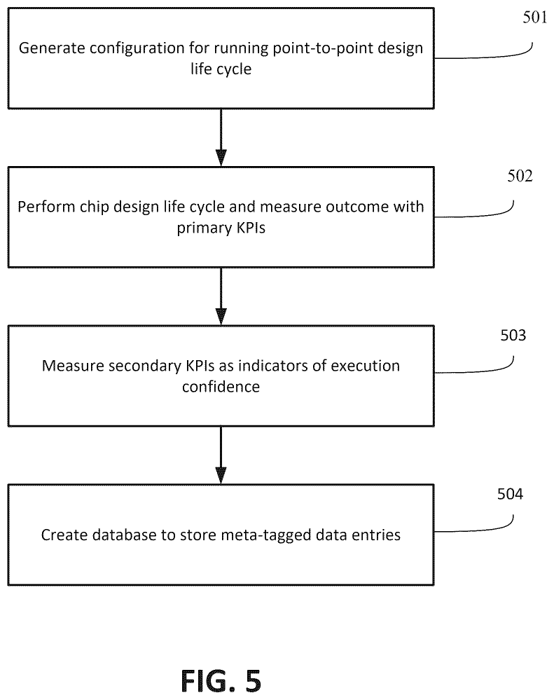

FIG. 5 is a flow chart illustrating a method of creating a database, according to an embodiment. For example, the method of FIG. 5 may be performed in step 401 of FIG. 4.

Referring to FIG. 5, in step 501, a configuration for running point-to-point design life cycle is generated. More specifically, an all-in-one configuration may be generated for running a point-to-point chip design life cycle. The configuration may be a unique identifier for a design, e.g., a vector with up to 50,000 dimensions.

In step 502, the process includes performing the chip design life cycle and measuring an outcome with primary KPIs, e.g., in performance (timing), power (leakage, dynamic, memory, clock), area, cost (CPU, memory, disk, yield, etc.) and turn-around-time (CPU hours).

In step 503, secondary KPIs are measured as indicators of execution confidence. The secondary KPIs may include completeness of runs, errors/warnings in log files, server crashes involved or not, PDK/DK version stability, identified bugs in vendor flows, etc.

In step 504, a database is created to store meta-tagged data entries, e.g., in the volume of 1-10 million. The database may also be optimized, e.g., with additional association tables/inner-joins of tables for fields frequently queried to boost access performance.

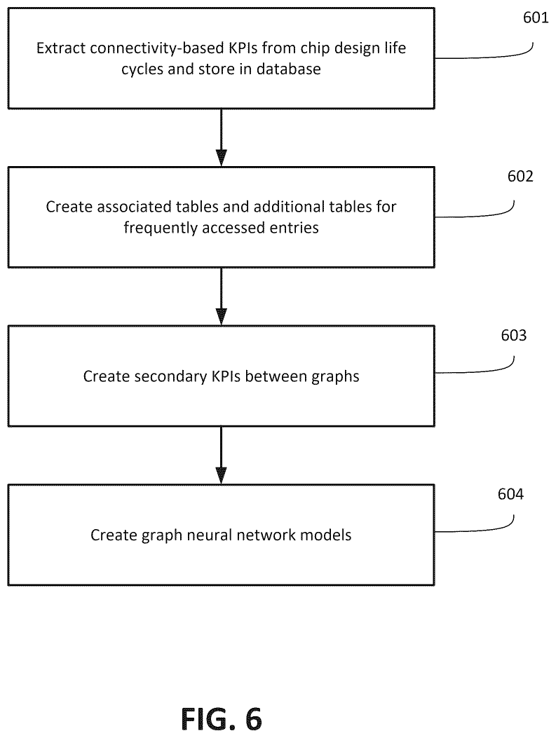

FIG. 6 is a flow chart illustrating a method of performing graph analysis, according to an embodiment. For example, the method of FIG. 6 may be performed in step 402 of FIG. 4.

Referring to FIG. 6, in step 601, connectivity-based KPIs are extracted from chip design life cycles and stored in a database. That is, connectivity-based KPIs are extracted from chip design life cycles and stored as graphs in a graph database.

In step 602, the process includes creating associated tables and additional tables for frequently accessed entries. The associated tables and additional tables for the frequently accessed entries may relate to register transfer level (RTL) (e.g., a connectivity graph), pin density/cell congestion (e.g., heatmap graphs), signal propagations/clock & power gating circuits (e.g., dependency graphs), and/or design for testability (DFT) logics (e.g., scan chain graphs).

In step 603, secondary KPIs are created between graphs. These secondary KPIs may be used as additional meta data tags to discover cross-correlations. That is, graphical features, e.g., cones, and cell distribution may be correlated to reveal trends/insights.

In step 604, graph neural network models created to visualize a graph solution space, identify weak coverage sub-spaces, and/or recommend additional chip design life-cycles with new data entries to the database.

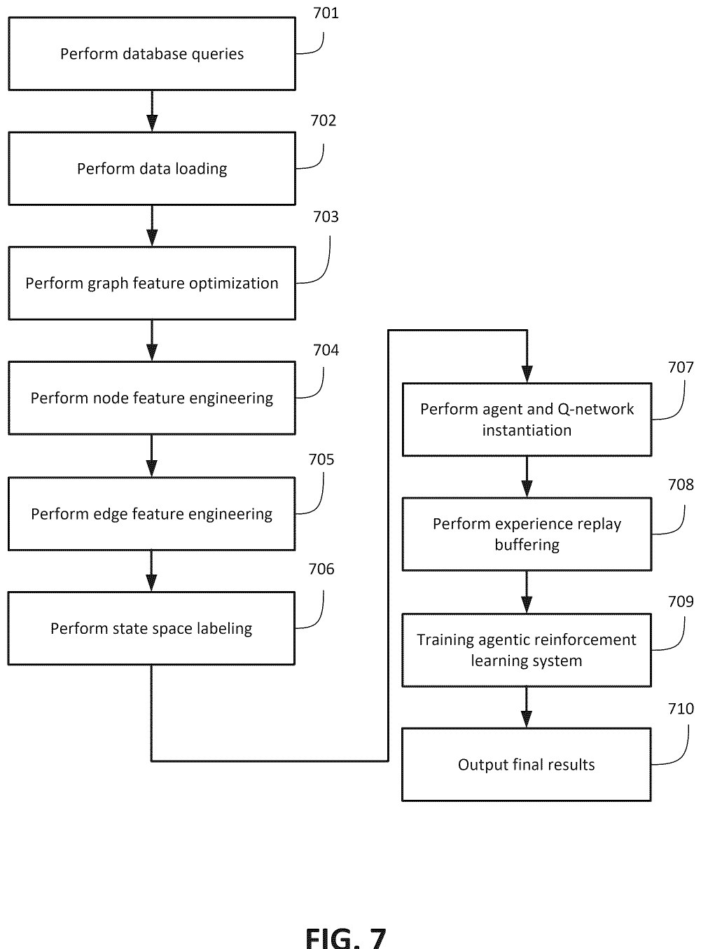

FIG. 7 is a flow chart illustrating a method utilizing RL to identify optimal design configurations, according to an embodiment. For example, the method of FIG. 7 may be performed in step 401 of FIG. 4.

Referring to FIG. 7, in step 701, the method includes perform database queries, e.g., a relational database and a graph database. More specifically, application programming interfaces (APIs) may be provided for simultaneous access of multiple applicational databases for input data in order to build an agentic RL system.

In step 702, data loading is performed. Per unique identifier (e.g., a high dimensional vector of configuration affecting chip PPA outcome), an initial data processing pipeline of the data intelligence system may be populated.

In step 703, graph feature optimization is performed. This process may include combining relevant graphs (timing, power, circuit-gating, etc.) associated to a unique identifier into one multi-graph as a single-entry feature.

In step 704, node feature engineering is performed. For example, for each node on the multi-graph, content representation may be optimized and additionally meta tag information may be added as necessary (e.g., for cell attributes, interconnect properties, etc.). Further, isolated nodes may be removed.

In step 705, edge feature engineering is performed. For example, for each edge on the multi-graph, content representation may be optimized and self-loops are removed to ensure acyclic graph properties. Additionally, isolated edges may be removed.

In step 706, state space labeling is performed. For example, the process may include labeling a PPA outcome (chip performance, power, area, cost, tat, etc.) associated to a multi-graph entry of a configuration vector. This process may also be used to prepare for subsequent agentic RL iterations.

For example, step 706 may utilized to associate PPA outcome to an input vectorized configuration efficiently, which is desirable due to the high dimensionality of the data involved.

Step 706 may also be utilized to perform additional preparations for subsequent RL steps.

Since graph objects are included in database queries results, in step 706, filters and weighing layers may be applied to convert data into formats that can be fed into subsequent steps. These may include but are not limited to convolutional filters (1D, 2D, or 3D) to perform best-case, worst-case, average-case data sampling, up-sampling/up-weighing certain aspects of graph metrics, such as degree of connectivity to critical nodes or similarities between graphs, which enables attention mechanism during the training of ML systems.

In step 707, the process includes agent and Q-network instantiation. More specifically, neural network architectures, layer details (sequential, convolutional), state space, action space, policy and reward mechanisms, etc., may be defined and initialized for iterative learning.

For example, to instantiate an RL system, there are three parts to be properly configured: an environment (e.g., databases as created by in steps 504 and 601 above), an action/state space (e.g., as created in step 706), and agents, e.g., as created in step 707.

An agent may be a software object that recommends an action, such as a change in the input configuration vector, and observes its PPA impacts at the end of one chip-design life-cycle. The agent may include a memory map that records the (action, reward) pair, which may be called a policy table.

Accordingly, step 707 may include defining a number of parallel agents, initiating a blank centralized policy table shared among all agents, and a mapping mechanism with a deep Q-network configuration. Over subsequent steps, the policy table may be iteratively updated and become the final “knowledge base” to predict best configurations to achieve best-case PPA.

In step 708, experience replay buffering is performed. For example, a replay buffer mechanism may be customized to allow repeated in-memory training and attention schemes to focus on low training confidence subsets of data. This enhancement may facilitate the proper handling the interpretation of multi-graph features.

In step 709, the process includes training an agentic reinforcement learning system. For example, iterative training/validation may be performed between environment (e.g., above set databases), reward (e.g., defined as a weighed sum of short-term and long-term expected return in chip outcome when configuration changes), action application (e.g., a recommended next step change), and states (e.g., a result of taking an action).

In step 710, final results are output. More specifically, after training is completed and cross-validation passes, a resulting policy will be interpreted and visualized to identify an optimal configuration for a desired chip PPA outcome. The model may also be used to predict how chip PPA outcome changes, e.g., if one or more of the configuration vary (i.e., what-if scenarios).

In accordance with the above-described embodiments, systems and methods are provided for collecting and leveraging data generated in semiconductor chip design, and co-optimizing foundry technologies and design features for improved PPA scores, storing and representing key data in chip building steps with unique data structures and exploring insights with AI/ML algorithms/flows, deriving metrics and insights to score chip PPA, cost, and turn-around-time competitiveness, implementing targeted algorithms and AI methods to improve chip design and/or perform treat-offs to mitigate silicon risks, efficiently exploring solution spaces that have not been exploited due to compute resource and runtime limitations, fully leveraging chip design data through automated AI and ML flows, and providing algorithms/methods/visualizations to handle challenging chip design features inside mobile GPUs, such as advanced gaming, low power modes, and automobile applications, etc.

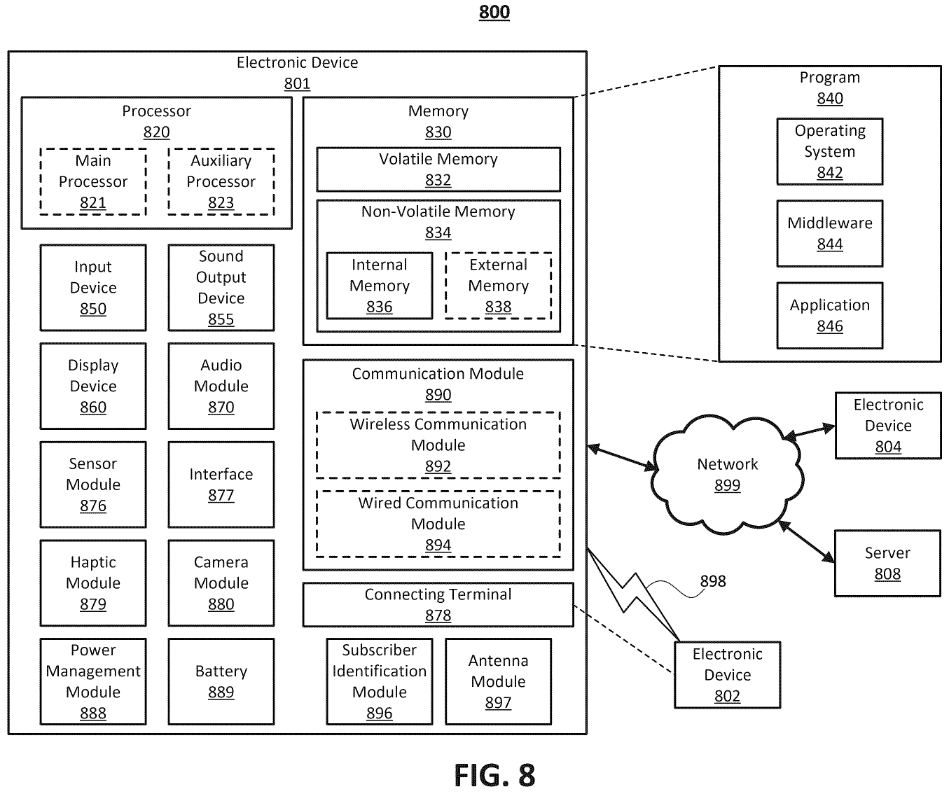

FIG. 8 is a block diagram of an electronic device in a network environment 800, according to an embodiment.

Referring to FIG. 8, an electronic device 801 in a network environment 800 may communicate with an electronic device 802 via a first network 898 (e.g., a short-range wireless communication network), or an electronic device 804 or a server 808 via a second network 899 (e.g., a long-range wireless communication network). The electronic device 801 may communicate with the electronic device 804 via the server 808. The electronic device 801 may include a processor 820, a memory 830, an input device 850, a sound output device 855, a display device 860, an audio module 870, a sensor module 876, an interface 877, a haptic module 879, a camera module 880, a power management module 888, a battery 889, a communication module 890, a subscriber identification module (SIM) card 896, or an antenna module 897. In one embodiment, at least one (e.g., the display device 860 or the camera module 880) of the components may be omitted from the electronic device 801, or one or more other components may be added to the electronic device 801. Some of the components may be implemented as a single integrated circuit (IC). For example, the sensor module 876 (e.g., a fingerprint sensor, an iris sensor, or an illuminance sensor) may be embedded in the display device 860 (e.g., a display).

The processor 820 may execute software (e.g., a program 840) to control at least one other component (e.g., a hardware or a software component) of the electronic device 801 coupled with the processor 820 and may perform various data processing or computations, e.g., the methods illustrated in FIG. 4-7.

As at least part of the data processing or computations, the processor 820 may load a command or data received from another component (e.g., the sensor module 876 or the communication module 890) in volatile memory 832, process the command or the data stored in the volatile memory 832, and store resulting data in non-volatile memory 834. The processor 820 may include a main processor 821 (e.g., a central processing unit (CPU) or an application processor (AP)), and an auxiliary processor 823 (e.g., a graphics processing unit (GPU), an image signal processor (ISP), a sensor hub processor, or a communication processor (CP)) that is operable independently from, or in conjunction with, the main processor 821. Additionally or alternatively, the auxiliary processor 823 may be adapted to consume less power than the main processor 821, or execute a particular function. The auxiliary processor 823 may be implemented as being separate from, or a part of, the main processor 821.

The auxiliary processor 823 may control at least some of the functions or states related to at least one component (e.g., the display device 860, the sensor module 876, or the communication module 890) among the components of the electronic device 801, instead of the main processor 821 while the main processor 821 is in an inactive (e.g., sleep) state, or together with the main processor 821 while the main processor 821 is in an active state (e.g., executing an application). The auxiliary processor 823 (e.g., an image signal processor or a communication processor) may be implemented as part of another component (e.g., the camera module 880 or the communication module 890) functionally related to the auxiliary processor 823.

The memory 830 may store various data used by at least one component (e.g., the processor 820 or the sensor module 876) of the electronic device 801. The various data may include, for example, software (e.g., the program 840) and input data or output data for a command related thereto. The memory 830 may include the volatile memory 832 or the non-volatile memory 834. Non-volatile memory 834 may include internal memory 836 and/or external memory 838.

The program 840 may be stored in the memory 830 as software, and may include, for example, an operating system (OS) 842, middleware 844, or an application 846.

The input device 850 may receive a command or data to be used by another component (e.g., the processor 820) of the electronic device 801, from the outside (e.g., a user) of the electronic device 801. The input device 850 may include, for example, a microphone, a mouse, or a keyboard.

The sound output device 855 may output sound signals to the outside of the electronic device 801. The sound output device 855 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 860 may visually provide information to the outside (e.g., a user) of the electronic device 801. The display device 860 may include, for example, a display, a hologram device, or a projector and control circuitry to control a corresponding one of the display, hologram device, and projector. The display device 860 may include touch circuitry adapted to detect a touch, or sensor circuitry (e.g., a pressure sensor) adapted to measure the intensity of force incurred by the touch.

The audio module 870 may convert a sound into an electrical signal and vice versa. The audio module 870 may obtain the sound via the input device 850 or output the sound via the sound output device 855 or a headphone of an external electronic device 802 directly (e.g., wired) or wirelessly coupled with the electronic device 801.

The sensor module 876 may detect an operational state (e.g., power or temperature) of the electronic device 801 or an environmental state (e.g., a state of a user) external to the electronic device 801, and then generate an electrical signal or data value corresponding to the detected state. The sensor module 876 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 877 may support one or more specified protocols to be used for the electronic device 801 to be coupled with the external electronic device 802 directly (e.g., wired) or wirelessly. The interface 877 may include, for example, a high-definition multimedia interface (HDMI), a universal serial bus (USB) interface, a secure digital (SD) card interface, or an audio interface.

A connecting terminal 878 may include a connector via which the electronic device 801 may be physically connected with the external electronic device 802. The connecting terminal 878 may include, for example, an HDMI connector, a USB connector, an SD card connector, or an audio connector (e.g., a headphone connector).

The haptic module 879 may convert an electrical signal into a mechanical stimulus (e.g., a vibration or a movement) or an electrical stimulus which may be recognized by a user via tactile sensation or kinesthetic sensation. The haptic module 879 may include, for example, a motor, a piezoelectric element, or an electrical stimulator.

The camera module 880 may capture a still image or moving images. The camera module 880 may include one or more lenses, image sensors, image signal processors, or flashes. The power management module 888 may manage power supplied to the electronic device 801. The power management module 888 may be implemented as at least part of, for example, a power management integrated circuit (PMIC).

The battery 889 may supply power to at least one component of the electronic device 801. The battery 889 may include, for example, a primary cell which is not rechargeable, a secondary cell which is rechargeable, or a fuel cell.

The communication module 890 may support establishing a direct (e.g., wired) communication channel or a wireless communication channel between the electronic device 801 and the external electronic device (e.g., the electronic device 802, the electronic device 804, or the server 808) and performing communication via the established communication channel. The communication module 890 may include one or more communication processors that are operable independently from the processor 820 (e.g., the AP) and supports a direct (e.g., wired) communication or a wireless communication. The communication module 890 may include a wireless communication module 892 (e.g., a cellular communication module, a short-range wireless communication module, or a global navigation satellite system (GNSS) communication module) or a wired communication module 894 (e.g., a local area network (LAN) communication module or a power line communication (PLC) module). A corresponding one of these communication modules may communicate with the external electronic device via the first network 898 (e.g., a short-range communication network, such as BLUETOOTH™, wireless-fidelity (Wi-Fi) direct, or a standard of the Infrared Data Association (IrDA)) or the second network 899 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 892 may identify and authenticate the electronic device 801 in a communication network, such as the first network 898 or the second network 899, using subscriber information (e.g., international mobile subscriber identity (IMSI)) stored in the subscriber identification module 896.

The antenna module 897 may transmit or receive a signal or power to or from the outside (e.g., the external electronic device) of the electronic device 801. The antenna module 897 may include one or more antennas, and, therefrom, at least one antenna appropriate for a communication scheme used in the communication network, such as the first network 898 or the second network 899, may be selected, for example, by the communication module 890 (e.g., the wireless communication module 892). The signal or the power may then be transmitted or received between the communication module 890 and the external electronic device via the selected at least one antenna.

Commands or data may be transmitted or received between the electronic device 801 and the external electronic device 804 via the server 808 coupled with the second network 899. Each of the electronic devices 802 and 804 may be a device of a same type as, or a different type, from the electronic device 801. All or some of operations to be executed at the electronic device 801 may be executed at one or more of the external electronic devices 802, 804, or 808. For example, if the electronic device 801 should perform a function or a service automatically, or in response to a request from a user or another device, the electronic device 801, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 801. The electronic device 801 may provide the outcome, with or without further processing of the outcome, as at least part of a reply to the request. To that end, a cloud computing, distributed computing, or client-server computing technology may be used, for example.

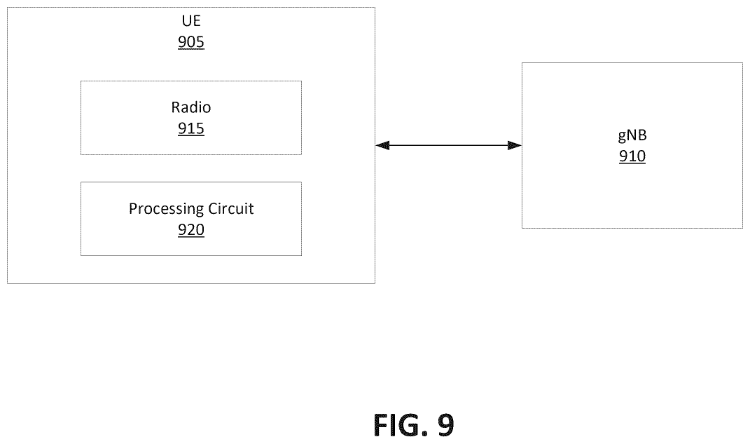

FIG. 9 shows a system including a UE and a gNB, in communication with each other.

Referring to FIG. 9, the UE 905 may include a radio 915 and a processing circuit (or a means for processing) 920, which may perform various methods disclosed herein, e.g., the methods illustrated in FIG. 4-7. For example, the processing circuit 920 may receive, via the radio 915, transmissions from the network node (gNB) 910, and the processing circuit 920 may transmit, via the radio 915, signals to the gNB 910.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method comprising:
generating a database including a plurality of entries corresponding to semiconductor chip design life cycles;
generating a graphical representation of at least one of the plurality of entries;
operating a framework including a plurality of techniques for identifying factors contributing to an optimal chip design, based on the graphical representation; and
outputting a completed chip design based on the identified factors.

2. The method of claim 1, wherein generating the database comprises:
generating a configuration for a executing a semiconductor chip design life cycle;
executing the semiconductor chip design life cycle and measuring an outcome with primary key performance indicators (KPIs);
measuring secondary KPIs as indicators of execution confidence; and
generating the database to store at least one meta-tagged data entry corresponding the semiconductor chip design life cycle, based on the primary and secondary KPIs.

3. The method of claim 1, wherein generating the graphical representation comprises:
extracting connectivity-based KPIs from chip design life cycles;
storing the connectivity-based KPIs as graphs in a graphing database;
generating tables for frequently accessed entries in the graphing database;
creating secondary KPIs as meta data tags for identifying cross-correlations between at least two of the graphs; and
generating a graph neural network model based on the connectivity-based KPIs and the secondary KPIs.

4. The method of claim 3, further comprising:
visualizing a graph solution space, based on the graph neural network model;
identify weak coverage sub-spaces based on the visualized graph solution space; and
recommending additional chip design life-cycles with new data entries to the database, based on the identifying.

5. The method of claim 1, wherein operating the framework comprises:
performing a database query;
loading data from the database based on the database query;
performing optimization on graph features of the data to generate a multi-graph;
performing node feature engineering on the multi-graph;
performing edge feature engineering on the multi-graph;
performing state space labeling on the multi-graph;
performing agent and Q-network instantiation based on the node feature engineering, the edge feature engineering, and the state space labeling;
performing experience replay buffering;
training an agentic reinforcement learning system; and
outputting an optimal configuration for a desired semiconductor chip design performance, based on the training.

6. The method of claim 1, wherein the graphical representation of at least one of the plurality of entries comprises at least one of a graph, a histogram, a heatmap, or a dynamic table.

7. The method of claim 1, wherein the graphical representation of at least one of the plurality of entries represent correlations between at least two graphs structures.

8. A computing device comprising:
at least one processor; and
memory configured to store instructions, which when executed by the at least one processor, control the processor to:
generate a database including a plurality of entries corresponding to semiconductor chip design life cycles,
generate a graphical representation of at least one of the plurality of entries,
operate a framework including a plurality of techniques for identifying factors contributing to an optimal chip design, based on the graphical representation, and
output a completed chip design based on the identified factors.

9. The computing device of claim 8, wherein the instructions, when executed by the at least one processor, further control the processor to generate the database by:
generating a configuration for a executing a semiconductor chip design life cycle;
executing the semiconductor chip design life cycle and measuring an outcome with primary key performance indicators (KPIs);
measuring secondary KPIs as indicators of execution confidence; and
generating the database to store at least one meta-tagged data entry corresponding the semiconductor chip design life cycle, based on the primary and secondary KPIs.

10. The computing device of claim 8, wherein the instructions, when executed by the at least one processor, further control the processor to generate the graphical representation by:
extracting connectivity-based KPIs from chip design life cycles;
storing the connectivity-based KPIs as graphs in a graphing database;
generating tables for frequently accessed entries in the graphing database;
creating secondary KPIs as meta data tags for identifying cross-correlations between at least two of the graphs; and
generating a graph neural network model based on the connectivity-based KPIs and the secondary KPIs.

11. The computing device of claim 10, wherein the instructions, when executed by the at least one processor, further control the processor to generate the graphical representation by:
visualizing a graph solution space, based on the graph neural network model;
identify weak coverage sub-spaces based on the visualized graph solution space; and
recommending additional chip design life-cycles with new data entries to the database, based on the identifying.

12. The computing device of claim 8, wherein the instructions, when executed by the at least one processor, further control the processor to operate the framework by:
performing a database query;
loading data from the database based on the database query;
performing optimization on graph features of the data to generate a multi-graph;
performing node feature engineering on the multi-graph;
performing edge feature engineering on the multi-graph;
performing state space labeling on the multi-graph;
performing agent and Q-network instantiation based on the node feature engineering, the edge feature engineering, and the state space labeling;
performing experience replay buffering;
training an agentic reinforcement learning system; and
outputting an optimal configuration for a desired semiconductor chip design performance, based on the training.

13. The computing device of claim 8, wherein the graphical representation of at least one of the plurality of entries comprises at least one of a graph, a histogram, a heatmap, or a dynamic table.

14. The computing device of claim 8, wherein the graphical representation of at least one of the plurality of entries represent correlations between at least two graphs structures.

15. A non-transitory computer readable medium storing program codes, which when executed by a computing device, control the computing device to:
generate a database including a plurality of entries corresponding to semiconductor chip design life cycles,
generate a graphical representation of at least one of the plurality of entries,
operate a framework including a plurality of techniques for identifying factors contributing to an optimal chip design, based on the graphical representation, and
output a completed chip design based on the identified factors.

16. The non-transitory computer readable medium of claim 15, wherein the program codes, when executed by the computing device, further control the computing device to generate the database by:
generating a configuration for a executing a semiconductor chip design life cycle;
executing the semiconductor chip design life cycle and measuring an outcome with primary key performance indicators (KPIs);
measuring secondary KPIs as indicators of execution confidence; and
generating the database to store at least one meta-tagged data entry corresponding the semiconductor chip design life cycle, based on the primary and secondary KPIs.

17. The non-transitory computer readable medium of claim 15, wherein the program codes, when executed by the computing device, further control the computing device to generate the graphical representation by:
extracting connectivity-based KPIs from chip design life cycles;
storing the connectivity-based KPIs as graphs in a graphing database;
generating tables for frequently accessed entries in the graphing database;
creating secondary KPIs as meta data tags for identifying cross-correlations between at least two of the graphs; and
generating a graph neural network model based on the connectivity-based KPIs and the secondary KPIs.

18. The non-transitory computer readable medium of claim 17, wherein the program codes, when executed by the computing device, further control the computing device to generate the graphical representation by:
visualizing a graph solution space, based on the graph neural network model;
identify weak coverage sub-spaces based on the visualized graph solution space; and
recommending additional chip design life-cycles with new data entries to the database, based on the identifying.

19. The non-transitory computer readable medium of claim 15, wherein the program codes, when executed by the computing device, further control the computing device to operate the framework by:
performing a database query;
loading data from the database based on the database query;
performing optimization on graph features of the data to generate a multi-graph;
performing node feature engineering on the multi-graph;
performing edge feature engineering on the multi-graph;
performing state space labeling on the multi-graph;
performing agent and Q-network instantiation based on the node feature engineering, the edge feature engineering, and the state space labeling;
performing experience replay buffering;
training an agentic reinforcement learning system; and
outputting an optimal configuration for a desired semiconductor chip design performance, based on the training.

20. The non-transitory computer readable medium of claim 15, wherein the graphical representation of at least one of the plurality of entries comprises at least one of a graph, a histogram, a heatmap, or a dynamic table.
